(19) United States
(12) Patent Application Publication
(10) Pub. No.: US 2002/0014693 A1
(43) Pub. Date: Feb. 7, 2002

(54) Molded array package for facilitating device singulation

(76) Inventor: Jeffrey James Pollock, Cupertino, CA (US)

Correspondence Address: MCDERMOTT WILL & EMERY, 600 13TH STREET, N.W., WASHINGTON, DC, 20005-3096, US

(21) Appl. No.: 09/531,505

(22) Filed: Mar. 21, 2000

(51) Int. Cl. H01L 23/34

(52) U.S. Cl. 257/724

(57) ABSTRACT

Segmentation or singulation of an encapsulated, spaced-apart array of semiconductor devices into a plurality of discrete device packages is facilitated by forming a pattern of indentations in the upper, exposed surface of the encapsulant material in a pattern corresponding to and in vertical registry with the pattern of spaces between adjacent devices of the array. Segmentation of the array is performed by cutting along the indentations. Advantages provided by cutting along the indentations include a shortened time interval for the cutting (e.g., by sawing), reduced tendency for warping due to stresses present in the encapsulant material as a result of curing, and improved physical appearance of discrete device packages due to the chamfered edges resulting in reduced edge chipping during sawing.

### FIELD OF THE INVENTION

The present invention generally relates to semiconductor device packages and an improved method for manufacturing same. More specifically, the present invention relates to an improved device package design and method for facilitating singulation or segmentation of a device array package into a plurality of discrete semiconductor device packages.

### BACKGROUND OF THE INVENTION

Semiconductor devices, such as integrated circuit (IC) devices, are typically fabricated in the form of small, thin, and thus fragile, dies or chips which are electrically connected to a lead frame or other mounting by means of a plurality of very fine, fragile wires, and then protected from physical damage, environmentally-induced degradation, etc., by means of an encapsulant material which surrounds the die or chip and associated lead frame or mounting. According to conventional large-scale manufacturing technology, a plurality of individual IC dies or chips are physically secured and electrically connected to a common substrate, e.g., a laminated circuit board or ceramic-based substrate and then encapsulated, as by molding, within a layer of encapsulant material, typically an epoxy resin material. The common substrate can be in the form of a narrow strip which mounts on the surface thereof an array of devices composed of a single row of spaced-apart IC dies or chips, or the substrate can be in a wider form for mounting thereon a two-dimensional array composed of columns and rows of spaced-apart dies or chips. In either instance, a plurality of discrete device packages are obtained from the encapsulated array by segmenting the latter along a pattern of lines corresponding to the pattern of spaces between adjacent dies or chips. Segmentation of the encapsulated multi-device arrays is typically performed by cutting through the layers of encapsulant and substrate materials in the spaces, as by use of a dicing saw.

However, the above-described conventional encapsulating/sawing procedures entail a significant disadvantage in large-scale automated device manufacturing processing because of the time consuming nature of the sawing process. In addition, stresses within the encapsulant material induced by the molding process can induce warping of the encapsulant array, and the external appearance of the singulated device packages obtained by cutting by sawing through the molded encapsulant and substrate is frequently unsatisfactory.

Accordingly, there exists a need for improved means and methodology for reliable manufacture of encapsulated arrays of semiconductor IC devices and discrete semiconductor device packages therefrom, which means and methodology avoid the drawbacks and disadvantages attendant upon fabrication according to conventional manufacturing processes, which means and methodology are fully compatible with all aspects, including throughput requirements, of mass manufacturing techniques and instrumentalities.

The present invention, wherein indentations are formed in the upper, exposed surface of the encapsulant material in a pattern corresponding to and overlying the pattern of spaces between adjacent dies or chips of the encapsulated array, and segmentation of the encapsulated array is accomplished by cutting along the pattern of indentations, effectively addresses and solves the above-described problems and drawbacks by minimizing the material required to be cut, thus reducing the time for segmentation into discrete device packages, and by relieving molding-induced stresses in the encapsulant material, thereby eliminating, or at least substantially reducing deleterious warping of the encapsulated array. In addition, the chamfered edges of the discrete device packages provided by the indentations formed in the encapsulant body reduces edge chipping during sawing for singulation thereby improving the physical appearance of the discrete device packages. Further, the means and methodology provided by the instant invention enjoys diverse utility in the manufacture of discrete device packages from variously configured encapsulated multi-device arrays.

### DISCLOSURE OF THE INVENTION

An advantage of the present invention is an improved method of making an encapsulated array of semiconductor devices useful in forming therefrom at least one discrete device package.

Another advantage of the present invention is an improved method for segmenting an encapsulated array of semiconductor devices into at least one discrete device package.

Yet another advantage of the present invention is an improved encapsulated array of semiconductor devices suitable for forming at least one discrete device package therefrom.

Additional advantages and other features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to one aspect of the present invention, the foregoing and other advantages are obtained in part by a method of making at least one packaged semiconductor device, comprising the steps of:

(a) providing a substrate having a surface adapted for mounting thereon a plurality of semiconductor devices;

(b) providing the plurality of semiconductor devices;

(c) mounting the plurality of semiconductor devices on the substrate surface to form a spaced-apart array of semiconductor devices with the spaces between adjacent devices of the array forming a pattern;

(d) encapsulating at least the array of semiconductor devices in an encapsulant material, wherein the encapsulating comprises forming a pattern of indentations in the outer surface of the encapsulant material at locations overlying and corresponding to the pattern of spaces.

According to embodiments of the present invention, the method further comprises the step of:

(e) segmenting the encapsulated array of semiconductor devices along the indentations to form therefrom a plurality of discrete package semiconductor devices.

According to further embodiments of the present invention, step (c) comprises mounting the plurality of semiconductor devices on the substrate surface in an array comprising rows and columns; step (d) comprises forming a pattern of the indentations in the outer surface of the encapsulant material corresponding to and overlying the pattern of spaces between the rows and columns of the array; and step (e) comprises segmenting the encapsulated array of semiconductor devices along the pattern of indentations, as by cutting, e.g., utilizing a saw, typically a diamond-tipped dicing saw.

According to still further embodiments of the present invention, step (a) comprises providing a substrate including electrical circuitry and/or contacts for making electrical connections to each of the plurality of semiconductor devices.

According to particular embodiments of the present invention, step (a) comprises providing as the substrate a laminated circuit board substrate or a ceramic-based substrate; step (b) comprises providing a plurality of semiconductor integrated circuit (IC) devices in the form of dies or chips; and step (c) further comprises establishing electrical connections between each of the plurality of IC devices and the substrate.

According to yet further embodiments of the present invention, step (d) comprises encapsulating the array of semiconductor devices in the encapsulant material by molding, e.g., utilizing a semiconductor grade epoxy resin molding material; wherein step (d) further comprises forming the pattern of indentations as V-shaped indentations in the exposed upper surface of the encapsulant material by molding or embossing the encapsulant material corresponding to and overlying the pattern of spaces between adjacent semiconductor devices of the array.

According to another aspect of the present invention, an encapsulated array of semiconductor devices comprises:

a substrate having a surface for receiving a plurality of semiconductor devices thereon;

a plurality of semiconductor devices on the substrate surface arranged in a spaced-apart array with spaces between adjacent devices, the spaces forming a pattern;

an encapsulant material surrounding at least the plurality of semiconductor devices, the encapsulant material including in an outer surface thereof a plurality of indentations forming a pattern corresponding to and overlying the pattern of spaces between semiconductor devices, the indentations facilitating segmentation of the encapsulated array of semiconductor devices into a plurality of discrete package semiconductor devices.

According to embodiments of the present invention, the substrate comprises a laminated circuit board or ceramic-based substrate including electrical circuitry and/or contacts for making electrical connections to each of the plurality of semiconductor devices, each of which comprises an integrated circuit (IC) die or chip; each of the indentations forming a V-shaped groove in the outer surface of the encapsulant material, having a bottom angle of about 30°, and extending for a depth of about one-half of the thickness of the encapsulant material; and the encapsulant material comprises a semiconductor grade epoxy resin molding material.

Additional advantages and aspects of the present invention will become readily apparent to those skilled in the art from the following detailed description, wherein embodiments of the present invention are shown and described, simply by way of illustration of the best mode contemplated for practicing the present invention. As will be described, the present invention is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiments of the present invention can best be understood when read in conjunction with the following drawings (not drawn to scale but instead drawn as to best illustrate the features of the present invention), in which like reference numerals are employed throughout to designate similar features, wherein:

FIG. 1 is a simplified, schematic cross-sectional view illustrating a portion of a spaced-apart array of semiconductor devices on a common substrate;

FIG. 2 is a simplified, schematic cross-sectional view illustrating the array portion of FIG. 1 after encapsulation according to the present invention; and

FIG. 3 is a simplified plan view illustrating the columns and rows of spaced-apart semiconductor devices of the array portion of FIGS. 1-2.

### DESCRIPTION OF THE INVENTION

The present invention is based upon recognition that formation of a plurality of recesses or indentations, e.g., V-shaped indentations, in the upper exposed surface of an encapsulant material in a pattern which corresponds with and is in overlying registry with a pattern of spaces between adjacent ones of a spaced-apart array of semiconductor devices, provides a number of advantages over conventionally encapsulated device arrays (i.e., without indentations) and segmentation/singulation processing thereof. Advantages provided the present invention include, inter alia, a significant reduction in the time required for segmentation processing by cutting, e.g., sawing, of the array along the pattern of indentations to form a plurality of discrete device packages; reduction in warping of the encapsulated array by providing relaxation of stresses present in the molded encapsulant; and improvement in the physical appearance of the discrete device packages due to the chamfered edges provided by the indentation, which chamfered edges result in less edge chipping during cutting by sawing.

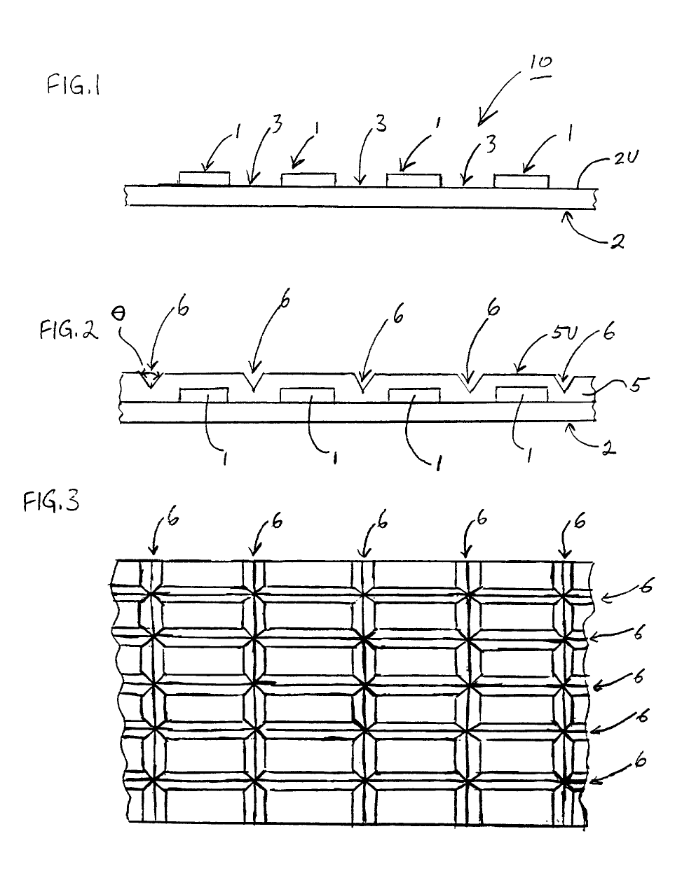

Referring now to FIG. 1, shown therein, in schematic, cross-sectional view is a portion of a conventional spaced-apart, unencapsulated array 10 of semiconductor devices 1 provided as a first step according to the invention. The semiconductor devices 1 contemplated for use herein typically comprise integrated circuit (IC) devices in the form of dies or chips with their associated electrical leads/contacts, each device 1 being physically secured (as by bonding) and electrically connected (by means not shown for illustrative simplicity and to not unnecessarily obscure the thrust of the present invention) to the upper major surface 2U of an elongated substrate 2, typically a laminated printed circuit board (PCB) or a ceramic-based substrate including suitable electrical circuitry and/or contacts, with spaces 3 between adjacent devices 1.

Adverting to FIG. 2, in a next step according to the inventive methodology, at least the upper portion of array 10, including the top and side edge surfaces of devices 1 and the portions of the upper major surface 2U of the substrate 2 exposed in spaces 3, are covered in conventional manner, e.g., by molding, with a layer 5 of an encapsulating material, e.g., a semiconductor grade epoxy resin molding material. If desired, the entire array 10, including the substrate 2, can be encapsulated within layer 5. According to the invention, a pattern of indentations 6 corresponding to and in vertical registry with the pattern of spaces 3 between adjacent semiconductor devices is formed in the upper surface 5U of the encapsulant layer 5. Indentations 6 preferably are formed by molding them in the upper surface SU of encapsulant layer 5 simultaneous with its application and molding, or they can be formed by embossing the upper surface 5U of encapsulant layer 5 with an appropriately configured tool, prior to complete hardening of the encapsulant material.

By way of illustration, but not limitation, each of the indentations 6 forms a V-shaped groove or trench extending for a depth of about one-half the thickness of the encapsulant layer 5, with, for example, an angle θ of about 30° between the outwardly tapering sides of the indentations. With reference to the plan view of FIG. 3 illustrating a two-dimensional spaced-apart array of semiconductor devices, it is apparent that the indentations 6 formed in the upper surface 5U of the encapsulant layer 5 form a grid-like pattern, i.e., a “chocolate bar” pattern.

A number of advantages over conventional segmentation/singulation processing utilizing non-indented encapsulated arrays are thus provided by use of the inventive methodology, wherein a pattern of indentations 6 corresponding to and in vertical registry with the pattern of spaces between adjacent devices 1 of the spaced-apart array 10 are formed in the upper surface 5U of the encapsulant layer 5, including, inter alia, substantially reduced intervals required for segmentation by cutting the array along the pattern of indentations into discrete device packages, due to the lesser amount of encapsulant material required to be removed by the cutting, e.g., sawing; reduced tendency for potentially harmful encapsulant stress-induced warping provided by the stress-relieving action of the indentations; and improvement in the physical appearance of the discrete device packages due to the chamfered edges which result in less edge chipping during cutting by sawing. Further, the inventive methodology is fully compatible with the throughput requirements of automated semiconductor device manufacture and the inventive concepts or principles are not limited to use with IC dies or chips but rather are applicable to performing rapid, reliable segmentation of all manner of components utilized in the manufacture of various electrical and electronic devices.

In the previous description, numerous specific details have been set forth, such as specific materials, structures, processes, etc., in order to provide a better understanding of the present invention. However, the present invention can be practiced without resorting to the details specifically set forth. In other instances, well-known processing techniques and structures have not been described in detail in order not to unnecessarily obscure the present invention.

Only the preferred embodiments of the present invention and but a few examples of its versatility are shown and described in the present invention. It is to be understood that the present invention is capable of use in various other combinations and environments and is susceptible of changes and/or modifications within the scope of the inventive concept as expressed herein.

What is claimed is:

1. A method of making at least one packaged semiconductor device, comprising the steps of:
(a) providing a substrate having a surface adapted for mounting thereon a plurality of semiconductor devices;
(b) providing said plurality of semiconductor devices;
(c) mounting said plurality of semiconductor devices on said substrate surface to form a spaced-apart array of semiconductor devices with the spaces between adjacent devices of the array forming a pattern;
(d) encapsulating at least said array of semiconductor devices in an encapsulant material, wherein said encapsulating comprises forming a pattern of indentations in the outer surface of said encapsulating material at locations overlying and corresponding to said pattern of spaces between adjacent semiconductor devices.

2. The method according to claim 1, further comprising the step of:
(e) segmenting the encapsulated array of semiconductor devices along said indentations to form a plurality of discrete package semiconductor devices.

3. The method according to claim 2, wherein:
step (c) comprises mounting said plurality of semiconductor devices on said substrate surface in a spaced-apart array comprising rows and columns;
step (d) comprises forming a pattern of said indentations in said outer surface of said encapsulating material corresponding to and overlying the pattern of spaces between said rows and columns of said array; and
step (e) comprises segmenting the encapsulated array of semiconductor devices along said pattern of indentations.

4. The method according to claim 2, wherein:
step (e) comprises segmenting said encapsulated array of semiconductor devices by cutting along said pattern of indentations.

5. The method according to claim 4, wherein:
step (e) comprises cutting by means of sawing.

6. The method according to claim 5, wherein:
step (e) comprises sawing utilizing a diamond-tipped dicing saw.

7. The method according to claim i, wherein:
step (a) comprises providing a substrate including electrical circuitry and/or contacts for making electrical connections to each of said plurality of semiconductor devices.

8. The method according to claim 7, wherein:
step (a) comprises providing a laminated circuit board substrate or a ceramic-based substrate.

9. The method according to claim 7, wherein:
step (b) comprises providing a plurality of semiconductor integrated circuit (IC) devices in the form of dies or chips.

10. The method according to claim 9, wherein:
step (c) further comprises establishing electrical connections between each of said plurality of IC devices and said substrate.

11. The method according to claim 1, wherein:
step (d) comprises encapsulating said array of semiconductor devices in said encapsulant material by molding.

12. The method according to claim 11, wherein:
step (d) comprises molding utilizing a semiconductor grade epoxy resin molding material as said encapsulant material.

13. The method according to claim 11, wherein:
step (d) further comprises forming said pattern of indentations by molding the outer surface of said encapsulant material at locations corresponding to and overlying said pattern of spaces between adjacent semiconductor devices of said array.

14. The method according to claim 11, wherein:
step (d) further comprises forming said pattern of indentations by embossing the outer surface of said encapsulant material at locations corresponding to and overlying said pattern of spaces between adjacent semiconductor devices of said array.

15. The method according to claim 11, wherein:
step (d) comprises forming a pattern of V-shaped indentations.

16. An encapsulated array of semiconductor devices, comprising:
a substrate having a surface;
a plurality of semiconductor devices on said substrate surface arranged in a spaced-apart array with spaces between adjacent devices, said spaces forming a pattern; and
an encapsulant material surrounding at least said plurality of semiconductor devices, said encapsulating material including in an outer surface thereof a plurality of indentations forming a pattern corresponding to and overlying said pattern of spaces between adjacent semiconductor devices, said indentations facilitating cutting of said encapsulated array of semiconductor devices along said indentations into a plurality of discrete package semiconductor devices.

17. The array as in claim 16, wherein:
said substrate comprises a laminated circuit board or ceramic-based substrate including electrical circuitry and/or contacts for making electrical connections to each of said plurality of semiconductor devices; and
each of said plurality of semiconductor devices comprises an integrated circuit (IC) die or chip.

18. The array as in claim 17, wherein:
each of said plurality of indentations forms a V-shaped groove in the outer surface of said encapsulant material.

19. The array as in claim 18, wherein:
each of said V-shaped grooves includes a bottom angle of about 30° and extends for a depth of about one-half of the thickness of said encapsulant material.

20. The array as in claim 19, wherein:
said encapsulant material comprises a semiconductor grade epoxy resin molding material.
